(19) United States
(12) Patent Application Publication
(10) Pub. No.: US 2025/0174876 A1
(43) Pub. Date: May 29, 2025

(54) ANTENNA MODULE AND COMMUNICATION DEVICE HAVING THE SAME MOUNTED THEREON

(71) Applicant: Murata Manufacturing Co., Ltd., Nagaokakyo-shi (JP)

(72) Inventors: Naotaka OIWA, Nagaokakyo-shi (JP); Kengo ONAKA, Nagaokakyo-shi (JP)

(73) Assignee: Murata Manufacturing Co., Ltd., Nagaokakyo-shi (JP)

(21) Appl. No.: 19/034,597

(22) Filed: Jan. 23, 2025

Related U.S. Application Data
(63) Continuation of application No. PCT/JP2023/019276, filed on May 24, 2023.

(30) Foreign Application Priority Data
Oct. 3, 2022 (JP) 2022-159351

(51) Int. Cl. H01Q 1/22; H01F 27/24; H01F 27/28; H01L 23/538; H01L 25/18; H01Q 1/24; H01Q 1/48; H01Q 9/04

(52) U.S. Cl. CPC H01Q 1/2283; H01L 23/5385; H01L 23/5386; H01L 25/18; H01Q 1/241; H01Q 1/48; H01Q 9/0407; H01F 27/24; H01F 27/28; H01Q 1/2266; H01Q 1/243

(57) ABSTRACT

An antenna module includes: a first substrate having a first surface and a second surface facing each other; a second substrate having a third surface and a fourth surface facing each other and disposed such that the third surface faces the second surface of the first substrate; a radiation element provided on a first surface side of the first substrate; a first ground electrode provided in the first substrate and facing the radiation element in a normal direction of the first substrate; a power inductor provided closer to the second substrate than the first ground electrode in plan view in a normal direction of the first substrate; and an electronic component provided on a fourth surface side of the second substrate and connected to the power inductor.

### CROSS-REFERENCE TO RELATED APPLICATIONS

This is a continuation application of PCT/JP2023/019276, filed on May 24, 2023, designating the United States of America, which is based on and claims priority to Japanese Patent Application No. JP 2022-159351 filed on Oct. 3, 2022. The entire contents of the above-identified applications, including the specifications, drawings and claims, are incorporated herein by reference in their entirety.

### TECHNICAL FIELD

The present disclosure relates to an antenna module and a communication device having the antenna module mounted thereon, and more particularly to a technology for suppressing deterioration of antenna characteristics.

### BACKGROUND ART

In recent years, in response to the demand for miniaturization and thinning of many devices to which an antenna module is applied, there has been a need to reduce the height of the antenna module. In general, an antenna module includes a substrate, and radiation element(s) and various electronic components mounted on the substrate. For example, Japanese Unexamined Patent Application Publication No. 2019-186741 (Patent Document 1) describes an antenna module in which an antenna element is mounted on one surface of a substrate and a plurality of electronic components are disposed on the other surface of the substrate.

### CITATION LIST

### Patent Document

Patent Document 1: Japanese Unexamined Patent Application Publication No. 2019-186741

### SUMMARY OF DISCLOSURE

### Technical Problem

Typical examples of the electronic components mounted on the substrate of the antenna module include an RFIC (Radio Frequency Integrated Circuit), a PMIC (Power Management Integrated Circuit), and a power inductor. By suppressing the height of the electronic components in the normal direction of the substrate surface, the height of the antenna module can be reduced. In particular, since the size of the power inductor is much larger than that of other electronic components, reducing the thickness of the power inductor is effective in reducing the height of the antenna module.

The power inductor is composed of a magnetic core and a winding wound around the magnetic core. In order to increase the DC superposition characteristics of the power inductor, it is necessary to increase the thickness of the magnetic core. Assuming the thickness of the power inductor is reduced to reduce the height of the antenna module, the DC superposition characteristics of the power inductor will be degraded, so that the antenna characteristics of the antenna module will be deteriorated.

The present disclosure is made to solve the above problem, and an object of the present disclosure is to reduce the height of the antenna module without deteriorating the antenna characteristics.

### Solution to Problem

An antenna module according to the present disclosure includes: a first substrate having a first surface and a second surface facing each other; a second substrate having a third surface and a fourth surface facing each other and disposed such that the third surface faces the second surface of the first substrate; a first ground electrode provided in the first substrate and facing a radiation element in a normal direction of the first substrate; a power inductor provided closer to the second substrate than the first ground electrode in plan view in the normal direction of the first substrate; and an electronic component provided on a fourth surface side of the second substrate and connected to the power inductor. The power inductor has a magnetic core, and a winding that straddles the first substrate and the second substrate and is wound around the magnetic core. A recess in which the magnetic core is disposed is provided on at least one of a second surface side of the first substrate and a third surface side of the second substrate.

### Advantageous Effects of Disclosure

According to the present disclosure, the height of the antenna module can be reduced without deteriorating the antenna characteristics.

### BRIEF DESCRIPTION OF DRAWINGS

FIG. 1 is a block diagram of a communication device to which an antenna module according to Embodiment 1 is applied.

FIG. 2 includes two parts: 2A, and 2B.

FIG. 2 is a plan view and a transparent side view of the antenna module of FIG. 1.

FIG. 3 includes two parts: 3A, and 3B.

FIG. 3 is a view showing a concrete example of a power inductor applied to the antenna module of FIG. 1.

FIG. 4 is a transparent side view of an antenna module according to Embodiment 2.

FIG. 5 is a transparent side view of an antenna module according to Embodiment 3.

FIG. 6 is a transparent side view of an antenna module according to Embodiment 4.

FIG. 7 is a transparent side view of an antenna module according to Embodiment 5.

FIG. 8 is a transparent side view of an antenna module according to Embodiment 6.

FIG. 9 is a block diagram of a communication device to which an antenna module according to Embodiment 7 is applied.

FIG. 10 is a plan view of the antenna module of FIG. 9.

FIG. 11 is a side view showing a state in which the antenna module of FIG. 9 is mounted.

FIG. 12 is a view for explaining a connection mode of feed lines to radiation elements in the antenna module of FIG. 9.

### DESCRIPTION OF EMBODIMENTS

Embodiments of the present disclosure will be described in detail below with reference to the drawings. It should be noted that the same or equivalent components in the drawings are denoted by the same reference signs and the in the drawings thereof are not repeated.

### Embodiment 1

### (Basic Configuration of Communication Device)

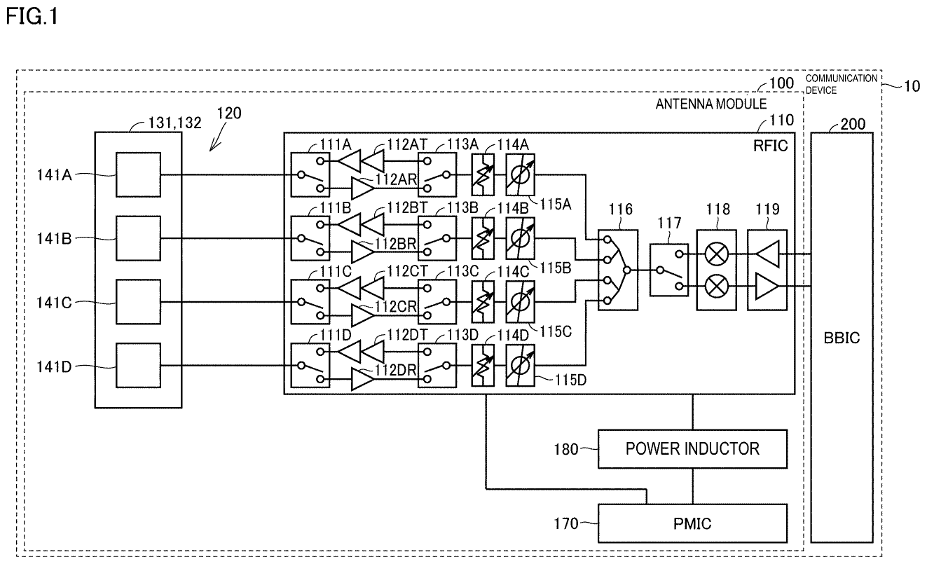

FIG. 1 is a block diagram of a communication device 10 to which an antenna module 100 according to Embodiment 1 is applied. The communication device 10 is, for example, a portable terminal such as a cellular phone, a smartphone and a tablet, or a personal computer having a communication function. One example of the frequency band of radio waves to be used in the antenna module 100 according to Embodiment 1 is, for example, a millimeter wave band with a center frequency of, for example, 28 GHz, 60 GHz and the like; however, radio waves in frequency bands other than those described above can also be applied to the antenna module according to present disclosure.

Referring to FIG. 1, a communication device 10 includes an antenna module 100 and a BBIC 200 that constitutes a baseband signal processing circuit. The antenna module 100 includes an RFIC 110, a PMIC 170, a power inductor 180, and an antenna device 120. The RFIC 110 and the PMIC 170 are examples of electronic components (feed circuit).

The PMIC 170 and the RFIC 110 are connected via a plurality of signal lines. A plurality of signal paths includes a path directly connecting the PMIC 170 and the RFIC 110, and a path connecting the PMIC 170 and the RFIC 110 via the power inductor 180. A feed signal is transmitted from the PMIC 170 to the RFIC 110 via the power inductor 180.

The communication device 10 up-converts a signal transmitted from the BBIC 200 to the antenna module 100 into a high-frequency signal by the RFIC 110, and radiates the up-converted signal from the antenna device 120. The communication device 10 transmits a high-frequency signal received by the antenna device 120 to the RFIC 110, down-converts the signal, and processes the down-converted signal by the BBIC 200.

The antenna device 120 includes dielectric substrates 131 and 132 and radiation elements 141A to 141D. The radiation elements 141A to 141D are each a patch antenna having a flat plate shape.

The radiation elements 141A to 141D are disposed on the dielectric substrate 131. The dielectric substrate 132 is disposed superimposed on the dielectric substrate 131. FIG. 1 shows an example of a one-dimensional array formed by arranging the radiation elements 141A to 141D in a row. Instead of such an arrangement, the radiation elements 141A to 141D may also be arranged in a two-dimensional array. The number of the radiation elements disposed on the dielectric substrate 131 is not limited to 4. One or more radiation elements may be disposed on the dielectric substrate 131.

The RFIC 110 includes switches 111A to 111D, 113A to 113D, and 117, power amplifiers 112AT to 112DT, low noise amplifiers 112AR to 112DR, attenuators 114A to 114D, phase shifters 115A to 115D, a signal combiner/splitter 116, a mixer 118, and an amplifier circuit 119.

Upon transmitting a high-frequency signal, the switches 111A to 111D, and 113A to 113D are switched to the side of the power amplifiers 112AT to 112DT, and the switch 117 is connected to a transmitting amplifier of the amplifier circuit 119. Upon receiving a high-frequency signal, the switches 111A to 111D, and 113A to 113D are switched to the side of the low noise amplifiers 112AR to 112DR, and the switch 117 is connected to a receiving amplifier of the amplifier circuit 119.

The signal transmitted from the BBIC 200 to the RFIC 110 is amplified by the amplifier circuit 119 and up-converted by the mixer 118. The transmission signal, which is the up-converted high-frequency signal, is split into four waves by the signal combiner/splitter 116, and the four waves pass through four signal paths and are fed to the radiation elements 141A to 141D. At this time, by adjusting the degree of phase shift of the phase shifters 115A to 115D disposed in each signal path individually, the directivity of the antenna device 120 can be adjusted. The attenuators 114A to 114D adjust the strength of the transmission signal.

The received signals, which are the high-frequency signals received by the radiation elements 141A to 141D, pass through four different signal paths respectively, and are combined by the signal combiner/splitter 116. The combined received signal is down-converted by the mixer 118, amplified by the amplifier circuit 119, and transmitted to the BBIC 200.

The RFIC 110 is formed, for example, as a single-chip integrated circuit component including the above-described circuit configuration. Alternatively, the RFIC 110 may also be formed as an individual integrated circuit component for each feed circuit. Further, the devices (i.e., the switches, the power amplifier, the low noise amplifier, the attenuator and the phase shifter) corresponding to each radiation element may be formed as a single-chip integrated circuit component for each corresponding radiation element.

### (Structure of Antenna Module)

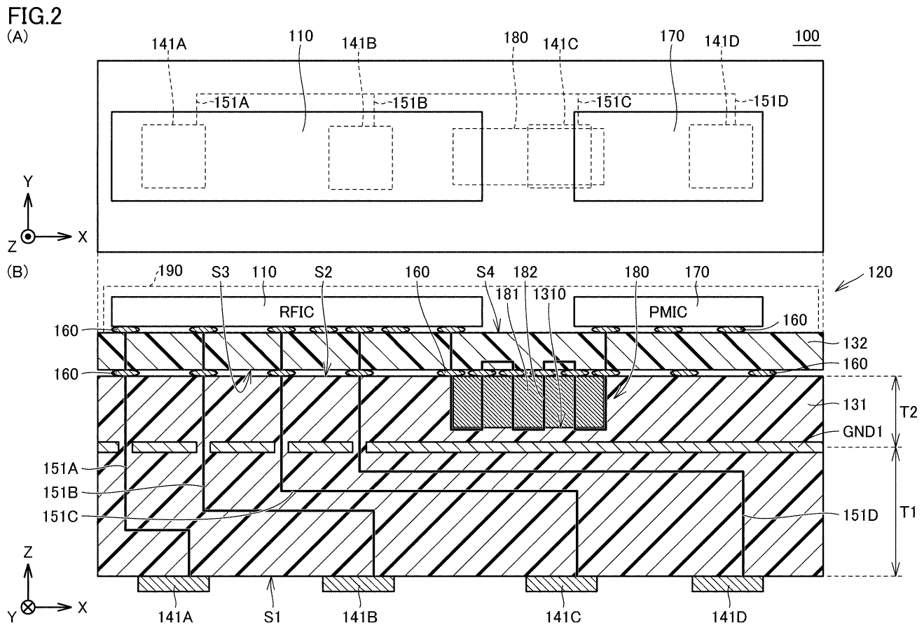

Next, the configuration of the antenna module 100 according to Embodiment 1 will be described in detail with reference to FIG. 2. FIG. 2 is a view showing the antenna module 100 according to Embodiment 1. In FIG. 2, the upper part (FIG. 2(A)) shows a plan view of the antenna module 100, and the lower part (FIG. 2(B)) shows a transparent side view of the antenna module 100.

The antenna module 100 includes the dielectric substrate 131, the dielectric substrate 132, feed lines 151A to 151D, and a ground electrode GND1 in addition to the radiation elements 141A to 141D, the RFIC 110, the PMIC 170, and the power inductor 180.

The dielectric substrates 131 and 132 each have a rectangular shape in plan view in the normal direction. The dielectric substrates 131 and 132 are each, for example, an LTCC (low temperature co-fired ceramic) multilayer substrate, a multilayer resin substrate formed by stacking a plurality of resin layers made of a resin such as epoxy or polyimide, a multilayer resin substrate formed by stacking a plurality of resin layers made of a LCP (liquid crystal polymer) having a lower dielectric constant, a multilayer resin substrate formed by stacking a plurality of resin layers made of a fluorine resin, a multilayer resin substrate formed by stacking a plurality of resin layers made of PET (polyethylene terephthalate), or a ceramic multilayer substrate other than an LTCC multilayer substrate. Note that the dielectric substrate 131 does not necessarily have a multilayer structure, but may be a single-layer substrate.

In the following description, the normal direction of the dielectric substrate 131 is defined as a Z-axis direction. In a plane perpendicular to the Z-axis direction, the arrangement direction of radiation elements 141A to 141D is defined as an X-axis, and the direction orthogonal to the X-axis is defined as a Y-axis.

As shown in FIG. 2, the dielectric substrates 131 and 132 are disposed to overlap each other in the Z-axis direction and are connected to each other by a plurality of solder bumps 160. A substrate surface S2 of the dielectric substrate 131 faces a substrate surface S3 of the dielectric substrate 132. The radiation elements 141A to 141D are disposed on a substrate surface S1 of the dielectric substrate 131.

The RFIC 110 and the PMIC 170 are disposed on a substrate surface S4 of the dielectric substrate 132. As shown by the broken line in FIG. 2, the RFIC 110 and the PMIC 170 may be sealed in a sealing body 190 to which a sealing resin and a sputter shield are applied. The RFIC 110 and the PMIC 170 are connected to the substrate surface S4 by a plurality of solder bumps 160. Alternatively, the RFIC 110 and the PMIC 170 may also be connected to the dielectric substrate 132 by a multipole connector provided on the substrate surface S4.

The radiation elements 141A to 141D are each an electrode having a rectangular flat plate shape. The radiation elements 141A to 141D are disposed on the dielectric substrate 131 in such a manner that they are exposed from the substrate surface S1. Alternatively, the radiation elements 141A to 141D may also be disposed within the dielectric substrate 131. High-frequency signals are supplied from the RFIC 110 to the radiation elements 141A to 141D via the feed lines 151A to 151D. The feed lines 151A to 151D are examples of feed lines that supply high-frequency signals outputted from the electronic components to the radiation elements.

The ground electrode GND1 faces the radiation elements 141A to 141D in the normal direction of the dielectric substrate 131. The ground electrode GND1 is disposed within the dielectric substrate 131 so as to cover substantially the entire area of a plane including the X-axis and the Y-axis within the dielectric substrate 131.

The power inductor 180 is positioned between the dielectric substrate 131 and the dielectric substrate 132. A ripple suppression capacitor may be disposed in a path between the power inductor 180 and the RFIC 110. Alternatively, to reduce the height, the ripple suppression capacitor may be embedded in the same position as the power inductor 180. Assuming the dielectric substrate 131 is viewed in plan view in direction orthogonal to the normal direction, the power inductor 180 is provided closer to the dielectric substrate 132 than the ground electrode GND1. The power inductor 180 is composed of a magnetic core 181 and a winding 182 wound around the magnetic core 181.

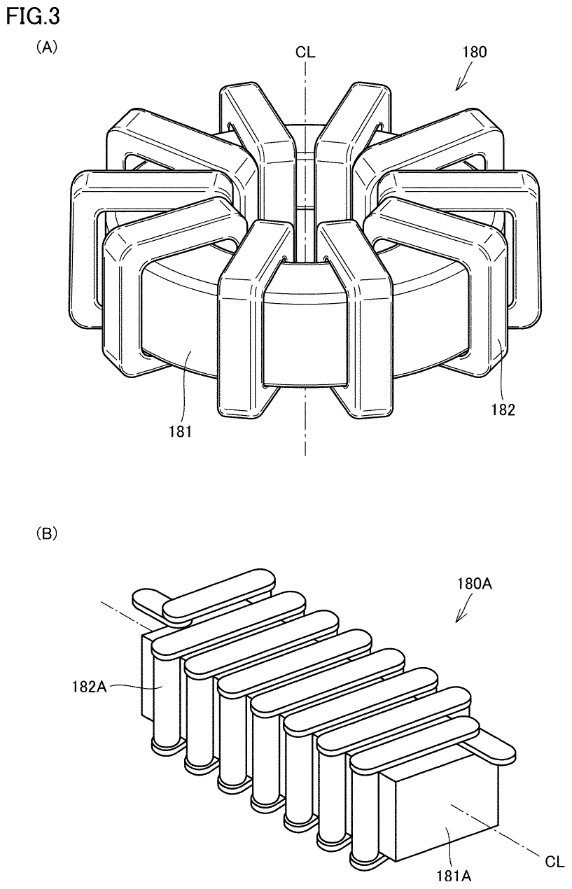

Here, a concrete example of the power inductor 180 will be described with reference to FIG. 3. FIG. 3 is a view showing a concrete example of a power inductor applied to the antenna module 100 of FIG. 1.

FIG. 3 (A) shows a power inductor 180 configured by a toroidal coil. As shown in FIG. 3 (A), the power inductor 180 configured by a toroidal coil is composed of a doughnut-shaped magnetic core 181 and a winding 182 wound around the magnetic core 181.

Unlike a coil using a rod-like core or the like, the toroidal coil has high stability because the amount of leakage of the magnetic flux within the winding 182 is small. Therefore, by employing the toroidal coil, the effect of high-frequency noise can be reduced. Assuming a toroidal coil is employed as the power inductor 180, the toroidal coil is disposed in a recess 1310 shown in FIG. 2 so that a virtual central axis CL is parallel to the Z-axis direction.

FIG. 3 (B) shows a power inductor 180A composed of a rod-like magnetic core 181A and a winding 182A. Such a power inductor 180A may be employed in the antenna module 100 instead of the power inductor 180 configured by a toroidal coil. Assuming the power inductor 180A is employed, the power inductor 180A is disposed in the recess 1310 shown in FIG. 2. At this time, it is desirable to dispose the power inductor 180A so that the virtual central axis CL passing through the center of the rod-like magnetic core 181A is parallel to the X-axis direction. With such an arrangement, the direction of the magnetic flux generated in the power inductor 180A is parallel to the X-axis direction. Therefore, assuming the power inductor is disposed so that the central axis CL is parallel to the X-axis direction, as compared with assuming the power inductor is disposed so that the central axis CL is perpendicular to the X-axis direction, the influence of the magnetic flux on the antenna and the RFIC 110 can be reduced, so that the stability of the antenna module 100 can be enhanced.

Returning to FIG. 2, the description of the antenna module 100 will be continued. As shown in FIG. 2(B), the recess 1310 for disposing the magnetic core 181 is formed on the side of the substrate surface S2 of the dielectric substrate 131. In a state in which the magnetic core 181 is disposed in the recess 1310, the surface of the magnetic core 181 on the side of the substrate surface S2 is flush with the substrate surface S2. The surface of the magnetic core 181 on the side of the substrate surface S2 is connected to the substrate surface S3 of the dielectric substrate 132 by the plurality of solder bumps 160.

The winding 182 straddles the dielectric substrate 131 and the dielectric substrate 132, and is wound around the magnetic core. The winding 182 is composed of via conductors that are formed on the dielectric substrate 131 and the dielectric substrate 132 and extended in the normal direction of the dielectric substrate 131, wires that are extended orthogonal to the normal direction of the dielectric substrate 131, and the solder bumps 160 that connect the surface of the magnetic core 181 on the side of the substrate surface S2 and the substrate surface S3 of the dielectric substrate 132.

One end of the winding 182 is connected to the PMIC 170, and the other end of the winding 182 is connected to the RFIC 110. The winding 182 constitutes a feed line that connects the RFIC 110 and the PMIC 170 via the magnetic core 181 of the power inductor 180. A feed signal is transmitted from the PMIC 170 to the RFIC 110 via the feed line composed of the winding 182. The RFIC 110 and the PMIC 170 are examples of electronic components connected to the power inductor 180. Of the winding 182, the winding on the dielectric substrate 132 may be composed only of the wires routed on the substrate surface S3. In such a configuration, the winding can be brought closer to the magnetic core 181 than in the case where the via conductors are included in the winding on the dielectric substrate 132. As a result, the DC superposition characteristics of the power inductor 180 can be further enhanced.

As described above, the antenna module 100 is constituted by overlapping the dielectric substrate 131, in which the magnetic core 181 is disposed in the recess 1310, with the dielectric substrate 132, on which electronic components such as the RFIC 110 and the PMIC 170 are mounted. Further, the power inductor 180 included in the antenna module 100 is formed by winding the winding 182 around the magnetic core 181 astride the dielectric substrate 131 and the dielectric substrate 132.

By constituting the antenna module 100 in such a manner, the thickness of the power inductor 180 in the Z-axis direction can be absorbed by the dielectric substrate 131. As a result, the thickness of the antenna module 100 in the Z-axis direction can be suppressed from being increased by the power inductor 180.

Instead of the magnetic core 181, it is also possible to dispose the RFIC 110 or PMIC 170 in the recess 1310. In the present embodiment, it is particularly advantageous to select the magnetic core 181 as the object to be disposed in the recess 1310 for the following reasons.

Firstly, since the power inductor 180 including the magnetic core 181 is much thicker than the other electronic components, reducing the effect of the thickness of the magnetic core 181 on the thickness of the antenna module 100 is effective in reducing the height of the antenna module. Secondly, there is room to make the RFIC 110 and the PMIC 170 thinner, while in the power inductor 180 the thickness of the magnetic core 181 must be increased to improve the DC superposition characteristics. Thirdly, since the RFIC 110 and the PMIC 170 generate a large amount of heat, assuming they are disposed between the dielectric substrate 131 and the dielectric substrate 132, it is necessary to provide a heat dissipation structure, and as a result, the structure becomes complicated.

For the above reasons, in the present embodiment, the magnetic core 181 of the power inductor 180 is selected as the object to be disposed in the recess 1310. According to the present embodiment, it is possible to reduce the height of the antenna module 100 without sacrificing the thickness of the power inductor 180, i.e., without deteriorating the antenna characteristics with the degradation of the DC superposition characteristics of the power inductor 180.

Further, in order to reduce the height of the antenna module 100, it is desirable to further reduce the thickness of the dielectric substrates 131 and 132 in the Z-axis direction. In such a case, it is necessary to design the thickness of the dielectric substrate 131 in consideration of the influence of the thickness of the substrate on the antenna characteristics of the radiation elements 141A to 141D. This is because assuming the dielectric substrate 131 is designed thin and therefore the distance between the radiation elements 141A to 141D and the ground electrode GND1 becomes short, good antenna characteristics cannot be obtained.

As shown in FIG. 2(B), the region of the dielectric substrate 132 can be divided into a region T1 and a region T2 with the ground electrode GND1 as a boundary. The thickness of the region T1 in the Z-axis direction corresponds to the distance between the radiation elements 141A to 141D and the ground electrode GND1. In order to obtain good antenna characteristics, it is important to ensure a sufficient distance between the radiation elements 141A to 141D and the ground electrode GND1. Therefore, it is not desirable to reduce the thickness of the region T1 even upon aiming at reducing the height of the antenna module 100.

From such a viewpoint, in the present embodiment, the thickness of the region T2 is reduced while the thickness of the region T1, which affects the antenna characteristics, is maintained at an appropriate thickness. For example, the thickness of the region T2 is designed in consideration of the thickness of the power inductor 180 including the magnetic core 181. Thus, by further thinning the dielectric substrate 131, it is possible to further reduce the height of the antenna module 100 while suppressing degradation of the antenna characteristics.

As shown in FIG. 2(A), assuming the dielectric substrate 132 is viewed in plan view in the normal direction, the power inductor 180 and the PMIC 170 are disposed so as to overlap each other. Similarly, assuming the dielectric substrate 132 is viewed in plan view in the normal direction, the power inductor 180 and the RFIC 110 are disposed so as to overlap each other.

Thus, the size of the antenna module 100 in the X-axis direction can be reduced. Further, one end of the winding 182 of the power inductor 180 can be connected to the PMIC 170 at the shortest distance, and the other end of the winding 182 of the power inductor 180 can be connected to the RFIC 110 at the shortest distance. Thus, the length of the feed line connecting the PMIC 170 and the RFIC 110 can be shortened. Since the length of the feed line transmitting the high-frequency signal can be shortened in such a manner, high-frequency noise that adversely affects the antenna characteristics of the radiation element can be reduced. As a result, deterioration of the antenna characteristics of the antenna module 100 can be suppressed. Further, since the distance between the PMIC 170 and the RFIC 110 can be shortened, the size (area) of the dielectric substrate 132 can also be reduced. In Embodiment 1, the power inductor 180 is disposed in a region between the PMIC 170 and the RFIC 110 (see FIG. 2). Thus, the length of the feed line connecting the PMIC 170 and the RFIC 110 can be shortened. As a result, the high-frequency noise can be reduced.

As shown in FIG. 2(A), the feed lines 151A to 151D are wired through portions separated from the power inductor 180 in the Y-axis direction, instead of being wired through the inside of the power inductor 180. That is, in the antenna module 100, in plan view in the normal direction of the dielectric substrate 131, the feed lines 151A to 151D are disposed at positions that do not overlap with the power inductor 180. Thus, the feed lines 151A to 151D and the power inductor 180 can be disposed apart from each other. As a result, noise caused by the influence of the power inductor 180 can be suppressed from mixing into the signals flowing through the feed lines 151A to 151D.

More specifically, in the antenna module 100, the feed lines 151A to 151D are wired at positions that do not overlap the power inductor 180 in plan view in a direction (Y-axis direction) orthogonal to the normal direction of the dielectric substrate 131 and orthogonal to the long side of the dielectric substrate 131. Thus, the feed lines 151A to 151D and the power inductor 180 can be disposed apart from each other while the arrangement dimensions of the dielectric substrates 131 and 132 are limited. As a result, noise caused by the influence of the power inductor 180 can be suppressed from mixing into the signals flowing through the feed lines 151A to 151D.

As described above, according to Embodiment 1, it is possible to reduce the height of the antenna module without deteriorating the antenna characteristics. In particular, in Embodiment 1, since the power inductor 180 is disposed in the antenna module 100 using the thickness portion of the dielectric substrate 131, the influence of the thickness of the power inductor 180 on the thickness of the antenna module 100 can be reduced.

Here, an example has been described in which both the RFIC 110 and the PMIC 170 overlap with the power inductor 180 assuming the dielectric substrate 132 is viewed in plan view in the normal direction. Alternatively, only one of the RFIC 110 and the PMIC 170 may overlap with the power inductor 180 assuming the dielectric substrate 132 is viewed in plan view in the normal direction.

In Embodiment 1, an example in which the magnetic core 181 is disposed in the dielectric substrate 131 has been described, but the magnetic core 181 may alternatively be disposed in the dielectric substrate 132. In such a case, a recess instead of the recess 1310 may be provided on the substrate surface S3 side of the dielectric substrate 132.

### Embodiment 2

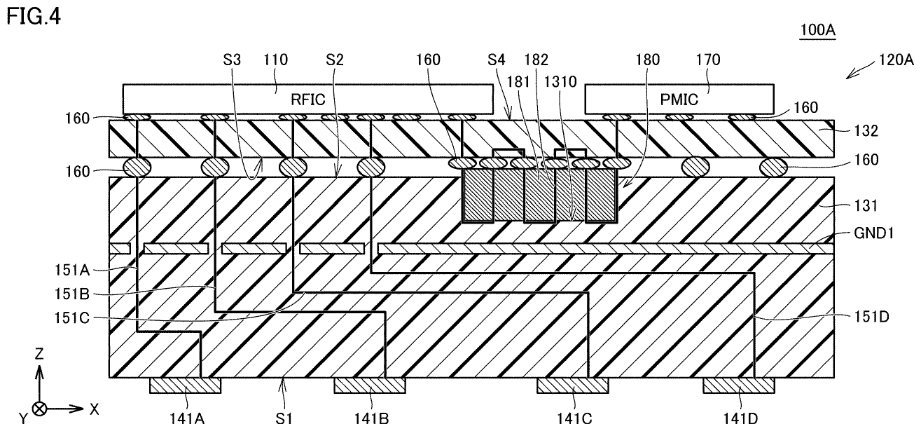

FIG. 4 is a transparent side view of an antenna module 100A according to Embodiment 2. The antenna module 100A includes an RFIC 110, a PMIC 170, and an antenna device 120A.

The antenna module 100A according to Embodiment 2 is different from the antenna module 100 according to Embodiment 1 in that a portion of a magnetic core 181 protrudes from a substrate surface S2. In the antenna module 100A according to Embodiment 2, a portion of the magnetic core 181 protrudes from the substrate surface S2, and the protruding portion is present in a space between a dielectric substrate 131 and a dielectric substrate 132.

In Embodiment 2, the magnetic core 181 protrudes from the substrate surface S2 toward the dielectric substrate 132. According to Embodiment 2, since it is not necessary to accommodate the entire magnetic core 181 in a recess 1310, the depth of the recess 1310 in the Z-axis direction can be made smaller than in Embodiment 1. Thus, the thickness of the dielectric substrate 131 can be made smaller. As a result, the height of the antenna module 100A can be further reduced.

In Embodiment 2, the depth of the recess 1310 in the Z-axis direction may also be made the same as in Embodiment 1. In such a case, a magnetic core thicker than the magnetic core 181 shown in FIG. 2 may be employed in Embodiment 2. Even assuming such a magnetic core is employed, the portion of the magnetic core protruding from the recess 1310 can be accommodated in the space between the dielectric substrate 131 and the dielectric substrate 132.

Thus, a power inductor 180 with more excellent DC superposition characteristics than in Embodiment 1 can be employed. Therefore, according to Embodiment 2, the performance of the antenna module 100A can be improved by employing the power inductor 180 with excellent DC superposition characteristics while reducing the height of the antenna module 100A.

As shown in FIG. 4, in Embodiment 2, a clearance is provided between the surface of the magnetic core 181 and a substrate surface S3 of the dielectric substrate 132. The purpose of providing such a clearance is to absorb variation in the size of the power inductor 180 that occurs during manufacture of the power inductor 180.

That is, by providing such a clearance, the magnetic core 181 can be accommodated between the dielectric substrate 131 and the dielectric substrate 132 even assuming there is some variation in the thickness of the magnetic core 181 constituting the power inductor 180 in the Z-axis direction. Alternatively, the size of the gap between the dielectric substrate 131 and the dielectric substrate 132 may be designed on the assumption that the surface of the magnetic core 181 is in contact with the substrate surface S3 of the dielectric substrate 132, without providing such a clearance.

The configuration of the antenna module 100A is the same as that of the antenna module 100 except that a portion of the magnetic core 181 protrudes from the substrate surface S2. Therefore, detailed descriptions of the other configurations of the antenna module 100A are not repeated here.

### Embodiment 3

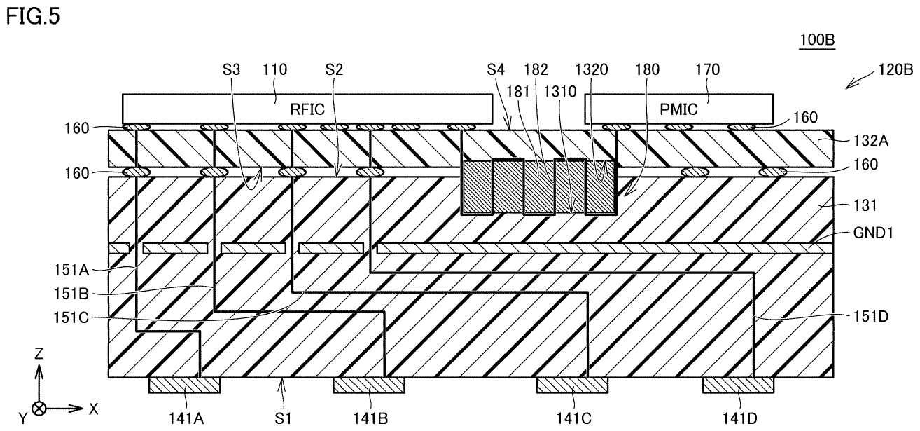

FIG. 5 is a transparent side view of an antenna module 100B according to Embodiment 3. The antenna module 100B includes an RFIC 110, a PMIC 170, and an antenna device 120B.

The antenna module 100B according to Embodiment 3 is different from the antenna module 100 according to Embodiment 1 in that a portion of a magnetic core 181 protrudes from a substrate surface S2 and a part of the protruding portion is disposed inside a dielectric substrate 132A. As shown in FIG. 5, a recess 1320 in which a part of the magnetic core 181 is disposed is formed on a substrate surface S3 side of the dielectric substrate 132A.

In Embodiment 3, the magnetic core 181 is disposed in: a recess 1310 of a dielectric substrate 131, the recess 1320 of the dielectric substrate 132A, and a space between the dielectric substrate 131 and the dielectric substrate 132A. The recess 1310 is an example of a first recess provided on a substrate surface S2 side of the dielectric substrate 131. The recess 1320 is an example of a second recess provided on a substrate surface S3 side of the dielectric substrate 132A and facing the first recess.

According to Embodiment 3, since it is not necessary to accommodate the entire magnetic core 181 in the recess 1310, the depth of the recess 1310 in the Z-axis direction can be made smaller than in Embodiment 1. Thus, the thickness of the dielectric substrate 131 can be made smaller. As a result, the height of the antenna module 100B can be further reduced.

In particular, in Embodiment 3, the thickness of the magnetic core 181 is absorbed by the recess 1310 formed in the dielectric substrate 131 and the recess 1320 formed in the dielectric substrate 132A. Therefore, according to Embodiment 3, the depth of the recess 1310 in the Z-axis direction can be made smaller than in Embodiment 2. As a result, according to Embodiment 3, the height of the antenna module 100B can be further reduced than in Embodiments 1 and 2.

In Embodiment 3, the depth of the recess 1310 in the Z-axis direction may be made the same as in Embodiment 1. In such a case, a magnetic core thicker than the magnetic core 181 shown in FIG. 2 may be employed in Embodiment 3. Even assuming such a magnetic core is employed, the portion of the magnetic core protruding from the recess 1310 can be accommodated in the space between the dielectric substrate 131 and the dielectric substrate 132A, and the recess 1320.

Thus, a power inductor 180 with more excellent DC superposition characteristics than in Embodiment 1 and Embodiment 2 can be employed. Therefore, according to Embodiment 3, the performance of the antenna module 100B can be improved by employing the power inductor 180 with excellent DC superposition characteristics while reducing the height of the antenna module 100B.

The configuration of the antenna module 100B is the same as that of the antenna module 100 except that a portion of the magnetic core 181 protrudes from the substrate surface S2 and a part of the protruding portion of the magnetic core 181 is positioned inside the dielectric substrate 132A. Therefore, detailed descriptions of the other configurations of the antenna module 100B are not be repeated here.

### Embodiment 4

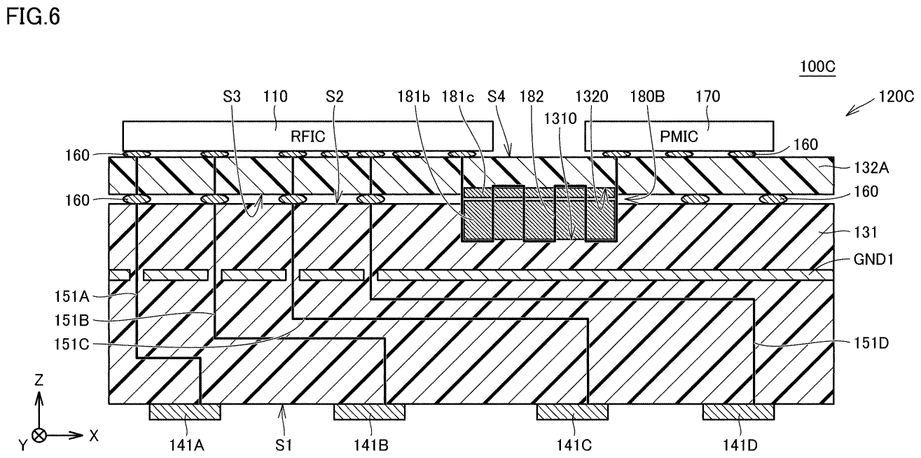

FIG. 6 is a transparent side view of an antenna module 100C according to Embodiment 4. The antenna module 100C includes an RFIC 110, a PMIC 170, and an antenna device 120C.

The antenna module 100C according to Embodiment 4 corresponds to a structure in which the magnetic core 181 of the antenna module 100B according to Embodiment 3 is split into two parts. As shown in FIG. 6, in the antenna module 100C according to Embodiment 4, a power inductor 180B is composed of a magnetic core 181b, a magnetic core 181c, and a winding 182 wound around the magnetic cores 181b and 181c.

The magnetic core 181b is disposed in a recess 1310. The magnetic core 181c is disposed in a recess 1320. The magnetic core 181b is an example of a first core. The magnetic core 181c is an example of a second core.

In the antenna module 100C according to Embodiment 4, there is a gap between the magnetic core 181b and the magnetic core 181c. In contrast, in the antenna module 100B according to Embodiment 3, since the magnetic core 181 is integrally formed, there is no such a gap.

Since the gap in the magnetic core may disturb the flow of magnetic flux, it may adversely affect the DC superposition characteristics of the power inductor. In this point, there is more room for providing an antenna module with higher antenna characteristics in Embodiment 3, in which an integrated type magnetic core 181 is employed, compared to Embodiment 4, in which split type magnetic cores 181b and 181c are employed.

However, assuming the split type magnetic cores 181b and 181c are employed, there is an advantage that the margins in the X-axis direction can be reduced when designing the recesses 1310 and 1320, as compared to the case in which the integrated type magnetic core 181 is employed. Details of the advantage will be described below.

When designing the sizes of the recesses 1310 and 1320 on the assumption that the integrated type magnetic core 181 is disposed between the dielectric substrates 131 and 132, it is necessary to determine the margins of the recesses 1310 and 1320 in the X-axis direction by considering the following two points.

The first point to be considered is the relationship between the size of the recesses 1310 and 1320 and the size of the magnetic core 181. Assuming the size of the former is larger than the size of the latter, the magnetic core 181 will not enter the recesses 1310 and 1320. Normally, a variation in the size of the magnetic core 181 occurs during the manufacturing process. Therefore, in consideration of the variation in the size of the magnetic core 181, it is necessary to design the size of the recesses 1310 and 1320 by providing a margin in the X-axis direction in each of the recess 1310 and the recess 1320.

The second point to be considered is, assuming the substrate surface S2 of the dielectric substrate 131 and the substrate surface S3 of the dielectric substrate 132 are superposed in a state where the magnetic core 181 has been disposed in one of the recesses 1310 and 1320, the positional relationship between the magnetic core 181 and the other of the recesses 1310 and 1320. Assuming such a positional relationship is largely deviated, there is a possibility that the magnetic core 181 does enter the other of the recesses 1310 and 1320 even assuming the recess 1310 and the recess 1320 are provided with margins in the X-axis direction in consideration of the variation in the size of the magnetic core 181.

Therefore, when designing the size of the recesses 1310 and 1320 on the assumption that the integrated type magnetic core 181 is disposed between the dielectric substrates 131 and 132, it is necessary to make the margins of the recesses 1310 and 1320 in the X-axis direction sufficiently large. As a result, the gap between the recesses 1310 and 1320 and the magnetic core 181 increases in the manufactured antenna module. As the gap between the recesses 1310 and 1320 and the magnetic core 181 increases, the size of the power inductor 180 decreases for the same occupied volume, and as a result, the DC superposition characteristics is degraded. On the other hand, upon trying to maintain the DC superposition characteristics, the volume of the recesses 1310 and 1320 must be increased, and as a result, the size of the dielectric substrate 131 increases.

In contrast, when designing the size of the recesses 1310 and 1320 on the assumption that the split type magnetic cores 181b and 181c are disposed between the dielectric substrates 131 and 132, the margins of the recesses 1310 and 1320 in the X-axis direction may be determined only by considering the relationship between the size of the recess 1310 and the size of the magnetic core 181b, and the relationship between the size of the recess 1320 and the size of the magnetic core 181c.

By determining the margin in such a manner, the magnetic core 181b can be disposed in the recess 1310 without any problem, and the magnetic core 181c can be disposed in the recess 1320 without any problem. The antenna module 100C shown in FIG. 6 can be manufactured by aligning the magnetic cores 181b and 181c assuming the dielectric substrate 131 having the magnetic core 181b disposed in the recess 1310 and the dielectric substrate 132 having the magnetic core 181c disposed in the recess 1320 are superposed. By manufacturing the antenna module 100C in such a manner, the gap between the recess 1310 and the magnetic core 181b and the gap between the recess 1320 and the magnetic core 181c can be reduced.

Therefore, assuming the split type magnetic cores 181b and 181c are employed, there is an advantage that the margin in the X-axis direction when designing the recesses 1310 and 1320 can be reduced, as compared with the case where the integrated type magnetic core 181 is employed. By reducing the margin in the X-axis direction, the size of the power inductor 180 can be prevented from being reduced, and as a result, desired DC superposition characteristics can be ensured. Also, the volume of the recesses 1310 and 1320 can be prevented from increasing, and as a result, the size of the dielectric substrate 131 can be prevented from increasing.

As described above, assuming the split type magnetic cores 181b and 181c are employed, the gaps present in the magnetic cores 181b and 181c may be a factor of disturbing the flow of magnetic flux. Therefore, in Embodiment 4, the cross-sectional area of the magnetic core 181b and the cross-sectional area of the magnetic core 181c, both facing each other across the gap of the magnetic cores 181b and 181c, are made equal to each other.

Thus, the flow of magnetic flux in the magnetic core 181b and the flow of magnetic flux in the magnetic core 181c become the same, so that it is possible to suppress the gap from obstructing the flow of magnetic flux. As a result, it is possible to realize a power inductor 180B capable of suppressing the deterioration of DC superposition characteristics even assuming the split type magnetic cores 181b and 181c are employed.

The configuration of the antenna module 100C is the same as that of the antenna module 100B except that the magnetic core is split into 2 parts. Therefore, detailed descriptions of other configurations of the antenna module 100C are not be repeated here.

### Embodiment 5

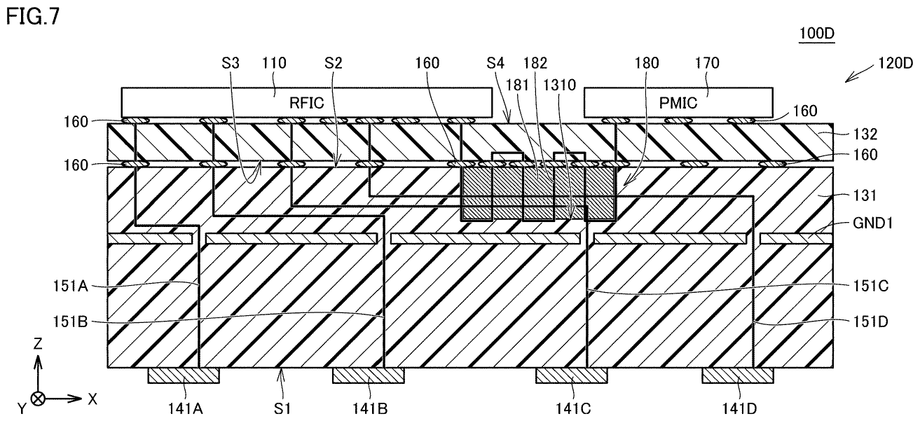

FIG. 7 is a transparent side view of an antenna module 100D according to Embodiment 5. The antenna module 100D includes an RFIC 110, a PMIC 170, and an antenna device 120D.

In the antenna module 100D according to Embodiment 5, the wiring paths of feed lines 151A to 151D are different from those of the antenna module 100 according to Embodiment 1. In particular, assuming a dielectric substrate 131 is viewed in plan view in the Y-axis direction (a direction orthogonal to the normal direction), the feed lines 151C and 151D are wired at positions overlapping with a power inductor 180. However, the feed lines 151C and 151D are wired through portions separated from the power inductor 180 in the Y-axis direction, instead of being wired through the inside of the power inductor 180.

In the example here, assuming the dielectric substrate 131 is viewed in plan view in the Y-axis direction (the direction orthogonal to the normal direction), the feed lines 151C and 151D among the feed lines 151A to 151D are wired so as to overlap with the power inductor 180. Alternatively, all of the feed lines 151A to 151D may be wired so as to overlap with the power inductor 180, depending on the size and arrangement position of the power inductor 180 in the X-axis direction.

In the above-described Embodiment 1, the feed lines 151A to 151D extending from the RFIC 110 toward the radiation elements 141A to 141D are developed in the X-axis direction using the region T1 of the dielectric substrate 131, and are connected to the radiation elements 141A to 141D. Therefore, in the case of Embodiment 1, it is necessary to ensure a thickness for developing the feed lines 151A to 151D in the X-axis direction in the region T1. As a result, there is a risk that the dielectric substrate 131 will become thick.

In contrast, in Embodiment 5, the feed lines 151A to 151D extending from the RFIC 110 toward the radiation elements 141A to 141D are developed in the X-axis direction using the region T2 of the dielectric substrate 131, and are connected to the radiation elements 141A to 141D. In particular, the feed lines 151C and 151D extending toward the radiation elements 141C and 141D pass through the positions where they overlap with the power inductor 180 assuming the dielectric substrate 131 is viewed in plan view in the Y-axis direction.

Assuming the feed lines 151C and 151D are wired so as to pass between the power inductor 180 and the ground electrode GND1, it is necessary to provide a space for wiring the feed lines 151C and 151D between the power inductor 180 and the ground electrode GND1. In such a case, it is necessary to make the region T2 thick. However, the thickness of the region T2 can be further reduced by wiring the feed lines 151C and 151D so that the feed lines 151C and 151D pass through the positions where they overlap with the power inductor 180 as described in Embodiment 5.

Note that the frequency band of the signals flowing through the feed lines 151A to 151D is significantly different from the frequency band of the signal flowing through the power inductor 180. Therefore, even assuming the feed lines 151A to 151D are wired near the power inductor 180, it is unlikely that unwanted electromagnetic field coupling will occur there to adversely affect the antenna characteristics.

In Embodiment 5, it is preferable to employ a power inductor 180 composed of a toroidal coil shown in FIG. 3(A). In the toroidal coil, since the amount of magnetic flux leakage in the winding 182 to the outside is small, the stability is high. Therefore, even assuming the feed lines 151A to 151D are wired next to the power inductor 180, interference of the magnetic flux generated by the power inductor 180 with the signals of the feed lines 151A to 151D can be suppressed.

Thus, in Embodiment 5, the feed lines 151C and 151D are wired so as to overlap with the power inductor 180 assuming the dielectric substrate 131 is viewed in plan view in the Y-axis direction. Thus, the region T2 can be made thin. Therefore, even assuming a magnetic core 181 thicker than the magnetic core 181 shown in FIG. 2 is employed in Embodiment 5, the increased thickness can be absorbed by devising the wiring of the feed lines. According to Embodiment 5, the performance of the antenna module 100D can be improved by employing the power inductor 180 with excellent DC superposition characteristics while reducing the height of the antenna module 100A.

The configuration of the antenna module 100D is the same as that of the antenna module 100 except for the wiring paths of the feed lines 151A to 151D. Therefore, detailed descriptions of the other configurations of the antenna module 100D are not be repeated here.

### Embodiment 6

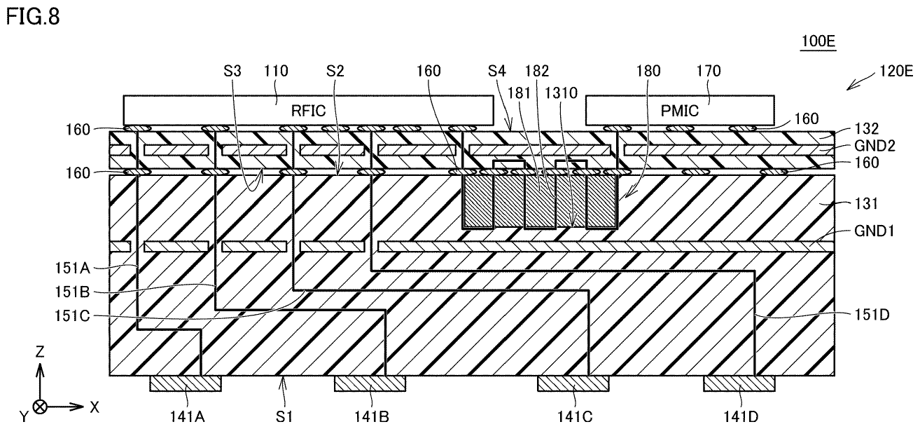

FIG. 8 is a transparent side view of an antenna module 100E according to Embodiment 6. The antenna module 100E includes an RFIC 110, a PMIC 170, and an antenna device 120E.

The antenna module 100E according to Embodiment 6 is different from the antenna module 100 according to Embodiment 1 in that a ground electrode GND2 is disposed on a dielectric substrate 132. In the antenna module 100E according to Embodiment 6, a power inductor 180 is disposed between a ground electrode GND1 on the side of a dielectric substrate 131 and the ground electrode GND2 on the side of the dielectric substrate 132.

According to Embodiment 6, electromagnetic field coupling that may occur between the power inductor 180 and radiation elements 141A to 141D can be suppressed by the ground electrode GND1, and electromagnetic field coupling that may occur between the power inductor 180 and the RFIC 110 and PMIC 170 can be suppressed by the ground electrode GND2. Thus, deterioration of the antenna characteristics of the antenna module 100E can be suppressed, and the amount of high-frequency noise that enters the RFIC 110 and PMIC 170 can be reduced.

The configuration of the antenna module 100E is the same as that of the antenna module 100 except that the ground electrode GND2 is disposed on the side of the dielectric substrate 132. Therefore, detailed descriptions of the other configurations of the antenna module 100E are not be repeated here.

In the present disclosure, 2 or 3 or more of the embodiments described above are to be combined.

### Embodiment 7

A mode of an antenna module for a base station to which the configuration of the power module is applicable will be described in Embodiment 7.

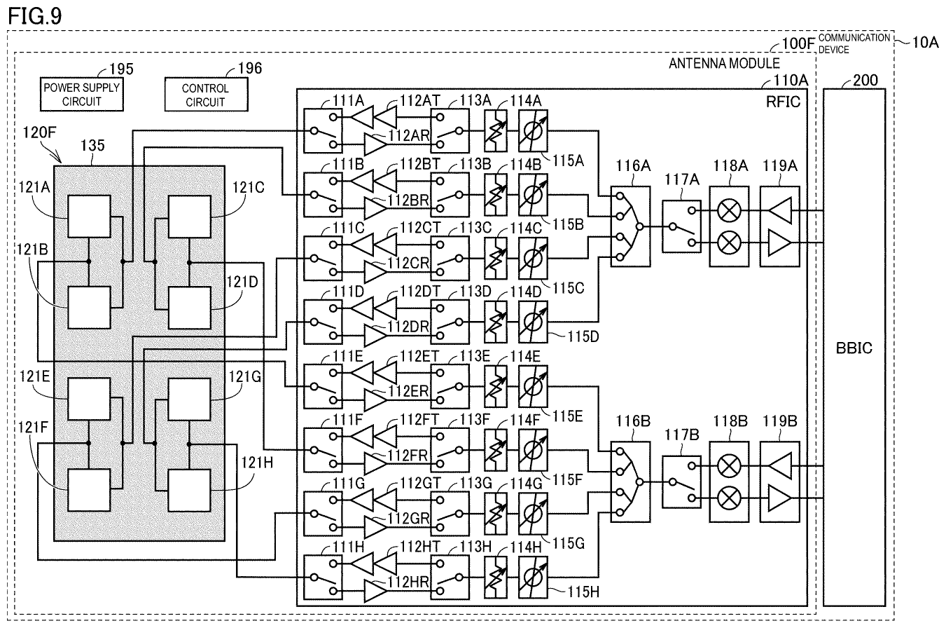

FIG. 9 is an example of a block diagram of a communication device 10A to which an antenna module 100F according to Embodiment 7 is applied. Referring to FIG. 9, similar to the communication device 10 shown in FIG. 1, the communication device 10A includes an antenna module 100F and a BBIC 200. The antenna module 100F includes an RFIC 110A, an antenna device 120F, a power supply circuit 195, and a control circuit 196.

The antenna device 120F of the antenna module 100F includes at least one antenna group, and one antenna group includes eight radiation elements. Note that, for sake of simplicity, FIG. 9 shows an example in which the antenna device 120F includes one antenna group, i.e., eight radiation elements that are radiation elements 121A to 121H. The radiation elements 121A˜121H are arranged in a 2×4 array on a dielectric substrate 135. In the following description, the plurality of radiation elements may be collectively referred to as “radiation element 121”.

The antenna group is divided into four element pairs. Each element pair includes two radiation elements that are adjacent to each other. Specifically, a first element pair includes the radiation elements 121A and 121B, a second element pair includes the radiation elements 121C and 121D, a third element pair includes the radiation elements 121E and 121F, and a fourth element pair includes the radiation elements 121G and 121H. As will be described later, high-frequency signals from a common feed line are supplied to the two radiation elements of each element pair.

In the antenna module 100F, one RFIC is provided for each antenna group. In other words, high-frequency signals are supplied from one RFIC to the eight radiation elements. Therefore, assuming the antenna module 100F includes a plurality of antenna groups, the same number of RFICs as the number of antenna groups will be provided.

The antenna module 100F is a so-called dual-band type antenna module that can radiate radio waves in two different polarization directions from each radiation element. Therefore, the RFIC 110A includes a circuit for supplying a high-frequency signal corresponding to a radio wave in a first polarization direction and a circuit for supplying a high-frequency signal corresponding to a radio wave in a second polarization direction.

Specifically, the RFIC 110A includes switches 111A to 111H, 113A to 113H, 117A, and 117B, power amplifiers 112AT to 112HT, low noise amplifiers 112AR to 112HR, attenuators 114A to 114H, phase shifters 115A to 115H, signal combiners/splitters 116A and 116B, mixers 118A and 118B, and amplifier circuits 119A and 119B. Among these components, the switches 111A to 111D, 113A to 113D, and 117A, the power amplifiers 112AT to 112DT, the low noise amplifiers 112AR to 112DR, the attenuators 114A to 114D, the phase shifters 115A to 115D, the signal combiner/splitter 116A, the mixer 118A, and the amplifier circuit 119A constitute a circuit for the first polarized wave. The switches 111E to 111H, 113E to 113H, and 117B, the power amplifiers 112ET to 112HT, the low noise amplifiers 112ER to 112HR, the attenuators 114E to 114H, the phase shifters 115E to 115H, the signal combiner/splitter 116B, the mixer 118B, and the amplifier circuit 119B constitute a circuit for the second polarized wave. Since the configuration of the circuit for each polarized wave is the same as that of the RFIC 110 shown in FIG. 1, the detailed description thereof will not be repeated.

To the radiation elements 121A and 121B of the first element pair, a high-frequency signal for the first polarized wave is supplied from the switch 111A, and a high-frequency signal for the second polarized wave is supplied from the switch 111E. To the radiation elements 121C and 121D of the second element pair, a high-frequency signal for the first polarized wave is supplied from the switch 111B, and a high-frequency signal for the second polarized wave is supplied from the switch 111F. To the radiation elements 121E and 121F of the third element pair, a high-frequency signal for the first polarized wave is supplied from the switch 111C, and a high-frequency signal for the second polarized wave is supplied from the switch 111G. To the radiation elements 121G and 121H of the fourth element pair, a high-frequency signal for the first polarized wave is supplied from the switch 111D, and a high-frequency signal for the second polarized wave is supplied from the switch 111H.

The power supply circuit 195 converts the voltage received from the outside of the antenna module 100F into a predetermined voltage, and generates a power supply voltage for operating the RFIC 110A, the control circuit 196, and the power supply circuit 195 itself. The power supply circuit 195 includes a PMIC 170 and a power inductor 180 as in Embodiment 1.

The control circuit 196 is a circuit for controlling active elements such as switches and amplifier circuits included in the RFIC 110A, and includes a control IC composed of, for example, a digital circuit.

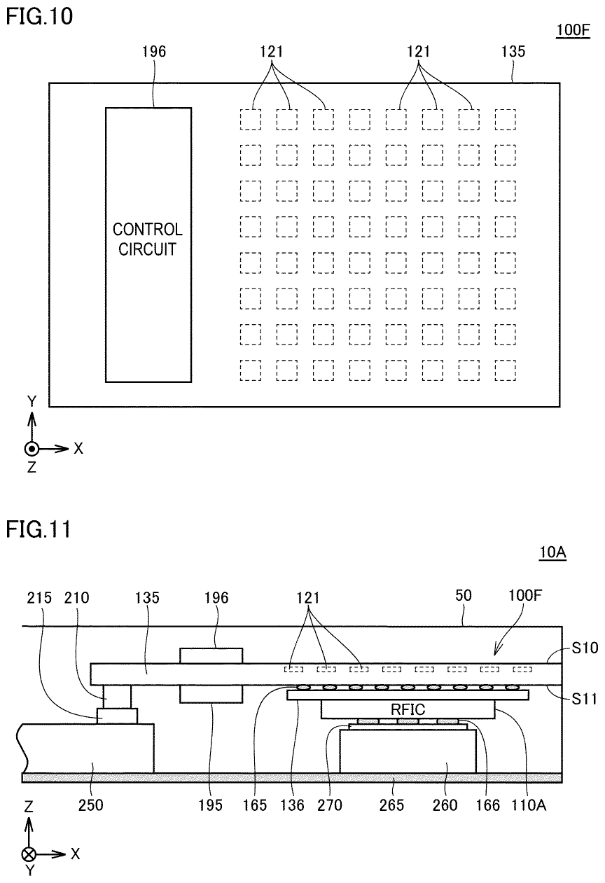

Next, a concrete configuration of the antenna module 100F will be described with reference to FIGS. 10 and 11. FIG. 10 is a plan view of the antenna module 100F of FIG. 9. FIG. 11 is a side view showing the inside of the communication device 10A in a state in which the antenna module 100F of FIG. 9 is mounted.

Referring to FIGS. 10 and 11, the antenna module 100F has the dielectric substrate 135 in which a plurality of radiation elements 121 are disposed, and a dielectric substrate 136 on which the RFIC 110A is mounted. Each of the dielectric substrates 135 and 136 has a flat plate shape, and has a substantially rectangular shape in plan view in the normal direction. In FIGS. 10 and 11, the normal direction of the dielectric substrate 135 is defined as a Z-axis direction, the long side direction is defined as an X-axis direction, and the short side direction is defined as a Y-axis direction.

As shown in FIG. 10, the dielectric substrate 135 has eight antenna groups, i.e., 64 radiation elements 121 arranged in an 8×8 array. In the example shown in FIGS. 10 and 11, the radiation elements 121 are disposed on the inner layer of the dielectric substrate 135, but the radiation elements 121 may alternatively be disposed to be exposed from a substrate surface S10 of the dielectric substrate 135 in the positive direction of the Z-axis.

Further, the dielectric substrate 136 is mounted by solder bumps 165 on a substrate surface S11 of the dielectric substrate 135 in the negative direction of the Z-axis, in a region under the radiation elements 121. The RFIC 110A is mounted on the dielectric substrate 136. A high-frequency signal is supplied from the RFIC 110A to each radiation element 121 via the solder bumps 165. Although not shown, the RFIC 110A in FIG. 11 includes eight pairs of the circuits that have been described with reference to FIG. 9.

The control circuit 196 is disposed on the substrate surface S10 of the dielectric substrate 135. The power supply circuit 195 is disposed on the substrate surface S11 of the dielectric substrate 135. Although the power supply circuit 195 is shown as a single element in FIG. 11, the elements included in the power supply circuit 195 may be arranged such that they are dispersed in the dielectric substrate 135.

At this time, the power inductor included in the power supply circuit 195 is disposed, for example, straddling the dielectric substrate 135 and the dielectric substrate 136. Alternatively, assuming the dielectric substrate 135 is composed of a combination of two different dielectric substrates, the power inductor is disposed straddling the two different dielectric substrates.

A connector 210 is disposed on the substrate surface S11 of the dielectric substrate 135. The connector 210 is configured to be connectable with a connector 215 of a mounting substrate 250 fixed to a casing 50 of the communication device 10A. By connecting the connector 210 with the connector 215, the antenna module 100F is mounted on the mounting substrate 250.

The surface of the RFIC 110A in the negative direction of the Z-axis is connected, via solder bumps 166, to a heat transfer member 270 disposed on a metal block 260. The heat transfer member 270 is formed of a member having a relatively high thermal conductivity, such as copper or aluminum. The metal block 260 is fixed to the casing 50 of the communication device 10A. That is, the RFIC 110A is supported by the metal block 260 and the heat transfer member 270. With such a configuration, since the heat generated in the RFIC 110A is dissipated through the heat transfer member 270, the metal block 260 and the casing 50, degradation in the characteristics of the RFIC 110A due to heat can be suppressed. As shown in FIG. 11, a heat sink 265 may be disposed between the metal block 260 and the casing 50 to further enhance the heat dissipation effect.

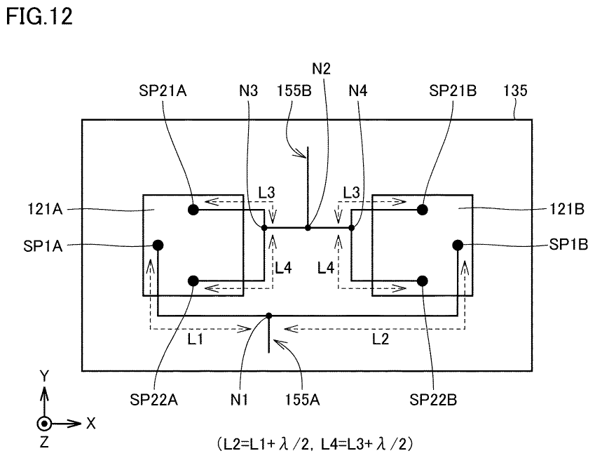

FIG. 12 is a view for explaining a connection mode of feed lines to the radiation elements in each element pair. In FIG. 12, the connection of the feed lines for the first element pair that includes the radiation elements 121A and 121B will be described as an example. In FIG. 12, the normal direction of the dielectric substrate 135 is defined as a Z-axis, the arrangement direction of the radiation elements 121A and 121B is defined as an X-axis, and the direction orthogonal to the X-axis and the Z-axis is defined as a Y-axis. The radiation element 121B is disposed away from the radiation element 121A in the positive direction of the X-axis.

Referring to FIG. 12, in each of the radiation elements 121A and 121B, one feed point for a radio wave with the X-axis direction as the polarization direction and two feed points for a radio wave with the Y-axis direction as the polarization direction are disposed. More specifically, in the radiation element 121A, a feed point SP1A is disposed at a position offset from the center of the radiation element 121A in the negative direction of the X-axis. Further, a feed point SP21A is disposed at a position offset from the center of the radiation element 121A in the positive direction of the Y-axis, and a feed point SP22A is disposed at a position offset from the center of the radiation element 121A in the negative direction of the Y-axis.

In the radiation element 121B, a feed point SP1B is disposed at a position offset from the center of the radiation element 121B in the positive direction of the X-axis. Further, a feed point SP21B is disposed at a position offset from the center of the radiation element 121B in the positive direction of the Y-axis, and a feed point SP22B is disposed at a position offset from the center of the radiation element 121B in the negative direction of the Y-axis.

A feed line 155A from the switch 111A (see FIG. 9) of the RFIC 110A branches at a branch point N1 and is connected to a feed point SP1A of the radiation element 121A and a feed point SP1B of the radiation element 121B. A feed line 155B from the switch 111E (see FIG. 9) of the RFIC 110A branches at a branch point N2, and one of the branches further branches at a branch point N3 and is connected to feed points SP21A and SP22A of the radiation element 121A. The other of the branches of the feed line 155B branched at the branch point N2 further branches at a branch point N4 and is connected to feed points SP21B and SP22B of the radiation element 121B.

Here, in the feed line 155A, the distance along the feed line 155A from the branch point N1 to the feed point SP1A of the radiation element 121A is represented by L1, and the distance along the feed line 155A from the branch point N1 to the feed point SP1B of the radiation element 121B is represented by L2 (L1<L2). Assuming λ represents the effective wavelength in the dielectric substrate of the radio waves radiated from the radiation elements 121A and 121B, the difference between the distance L1 and the distance L2 is set to be λ/2 or an odd multiple of λ/2. In other words, the phase of the high-frequency signal supplied to the feed point SP1A and the phase of the high-frequency signal supplied to the feed point SP1B are set to be opposite to each other.

As described above, the feed point SP1A of the radiation element 121A is offset from the center of the element in the negative direction of the X-axis, and the feed point SP1B of the radiation element 121B is offset from the center of the element in the positive direction of the X-axis. Therefore, assuming high-frequency signals of the same phase are supplied to the feed points SP1A and SP1B, radio waves of mutually opposite phases are radiated from the radiation elements 121A and 121B. Therefore, radio waves of the same phase can be radiated from the radiation elements 121A and 121B by supplying high-frequency signals of mutually opposite phases to the feed points SP1A and SP1B with different distances from the branch point N1 of the feed line 155A to the feed points SP1A and SP1B.

Next, a radio wave with the Y-axis direction as the polarization direction will be described. In the feed line 155B, the distance from the branch point N3 to the feed point SP21A and the distance from the branch point N4 to the feed point SP21B are represented by L3. In the feed line 155B, the distance from the branch point N3 to the feed point SP22A and the distance from the branch point N4 to the feed point SP22B are represented by L4 (L3<L4). Note that the distance between the branch point N2 and the branch point N3 and the distance between the branch point N2 and the branch point N4 are made the same.

Assuming λ represents the effective wavelength in the dielectric substrate of the radio waves radiated from the radiation elements 121A and 121B, the difference between the distance L3 and the distance L4 is set to be λ/2 or an odd multiple of λ/2. Thus, high-frequency signals of mutually opposite phases are supplied to the feed point SP21A and the feed point SP22A. Similarly, high-frequency signals of mutually opposite phases are supplied to the feed point SP21B and the feed point SP22B.

In the radiation element 121A, the feed point SP21A and the feed point SP22A are offset from the center of the radiation element 121A in mutually opposite directions of the Y-axis. Similarly, in the radiation element 121B, the feed point SP21B and the feed point SP22B are offset from the center of the radiation element 121B in mutually opposite directions of the Y-axis. Therefore, in each radiation element, by supplying high-frequency signals of mutually opposite phases to the two feed points, the phase of the radio waves corresponding to one of the two feed points becomes the same as the phase of the radio waves corresponding to the other of the two feed points.

Since the distances from the branch point N2 to the branch points N3 and N4 are set to be equal, the phases of the radio waves with the Y-axis direction as the polarization direction radiated from the radiation elements 121A and 121B are in the same phase.

By connecting the feed lines of the two radiation elements constituting the element pair in the above-described manner, the phases of the radio waves radiated in the respective polarization directions from the two radiation elements can be aligned, so that the antenna gain in the normal direction of the substrate can be maximized.

Note that the high-frequency signals supplied to the two feed points may be substantially in opposite phase, instead of being completely in opposite phase. In this specification, substantially in opposite phases includes a phase difference in a range of 180°±10°.

### [Aspects]

It is understood by those skilled in the art that each of the above-described embodiments is a concrete example of the following aspects.

(Clause 1) An antenna module comprising: a first substrate having a first surface and a second surface facing each other; a second substrate having a third surface and a fourth surface facing each other and disposed such that the third surface faces the second surface of the first substrate; a radiation element provided on a first surface side of the first substrate; a first ground electrode provided in the first substrate and facing the radiation element in a normal direction of the first substrate; a power inductor provided closer to the second substrate than the first ground electrode in plan view in the normal direction of the first substrate; and an electronic component provided on a fourth surface side of the second substrate and connected to the power inductor, wherein the power inductor has a magnetic core, and a winding that straddles the first substrate and the second substrate and is wound around the magnetic core, and a recess in which the magnetic core is disposed is provided on at least one of a second surface side of the first substrate and a third surface side of the second substrate.

(Clause 2) The antenna module according to clause 1, wherein the magnetic core is disposed to protrude from the second surface toward the second substrate.

(Clause 3) The antenna module according to clause 1 or 2, wherein the recess is a first recess provided on the second surface side of the first substrate, a second recess facing the first recess is provided on the third surface side of the second substrate, and the magnetic core is disposed in the first recess and the second recess.

(Clause 4) The antenna module according to clause 1 or 2, wherein the recess is a first recess provided on the second surface side of the first substrate, a second recess facing the first recess is provided on the third surface side of the second substrate, the magnetic core is split into a first core and a second core, the first core is disposed in the first recess, and the second core is disposed in the second recess.

(Clause 5) The antenna module according to any one of clauses 1 to 4, further comprising: a feed line disposed in the first substrate and supplying a signal outputted from the electronic component to the radiation element, wherein in plan view in the normal direction of the first substrate, the feed line is disposed at a position that does not overlap the power inductor.

(Clause 6) The antenna module according to any one of clauses 1 to 4, further comprising: a feed line disposed in the first substrate and supplying a signal outputted from the electronic component to the radiation element, wherein assuming the first substrate is viewed in plan view in a direction orthogonal to the normal direction, the feed line is wired at a position that overlaps the power inductor.

(Clause 7) The antenna module according to any one of clauses 1 to 4, further comprising: a feed line disposed in the first substrate and supplying a signal outputted from the electronic component to the radiation element, wherein the first substrate is a rectangular substrate with a long side and a short side, and in plan view in a direction orthogonal to the normal direction of the first substrate and orthogonal to the long side, the feed line is wired at a position that does not overlap the power inductor.

(Clause 8) The antenna module according to any one of clauses 1 to 7, further comprising: a second ground electrode disposed in the second substrate, wherein, in a normal direction of the second substrate, the power inductor is disposed between the first ground electrode and the second ground electrode.

(Clause 9) The antenna module according to any one of clauses 1 to 8, wherein the electronic component includes an RFIC (radio frequency integrated circuit), and a PMIC (power management integrated circuit), and assuming the second substrate is viewed in plan view in the normal direction, the power inductor overlaps at least one of the RFIC and the PMIC.

(Clause 10) The antenna module according to any one of clauses 1 to 9, wherein the power inductor is composed of a toroidal coil.

(Clause 11) A communication device comprising the antenna module according to any one of clauses 1 to 10 mounted thereon.

The embodiments disclosed herein are to be considered in all respects as exemplary and not restrictive. The scope of the present disclosure is indicated by the claims rather than by the description of the embodiments above, and is intended to include all modifications within the meanings and ranges equivalent to the scope of the claims.

### REFERENCE SIGNS LIST

10, 10A communication device
50 casing
100, 100A to 100F antenna module
110, 110A RFIC
111A to 111H, 113A to 113H, 117, 117A, 117B switch
112AR to 112HR low noise amplifier
112AT to 112HT power amplifier
114A to 114H attenuator
115A to 115H phase shifter
116, 116A, 116B signal combiner/splitter
118, 118A, 118B mixer
119, 119A, 119B amplifier circuit
120, 120A to 120F antenna device
121, 121A to 121H, 141, 141A to 141D radiation element
131, 132, 132A, 135, 136 dielectric substrate
151A to 151D, 155A, 155B feed line
160, 165, 166 solder bump
170 PMIC
180, 180A, 180B power inductor
181, 181A, 181b, 181c magnetic core
182, 182A winding
190 sealing body
195 power supply circuit
196 control circuit
200 BBIC
210, 215 connector
250 mounting substrate
260 metal block
265 heat sink
270 heat transfer member
1310, 1320 recess
CL central axis
GND1, GND2 ground electrode
S1 to S4, S10, S11 substrate surface
SP1A, SP1B, SP21A, SP21B, SP22A, SP22B feed point
T1, T2 thickness

1. An antenna module comprising:
a first substrate having a first surface and a second surface facing each other;
a second substrate having a third surface and a fourth surface facing each other and disposed such that the third surface faces the second surface of the first substrate;
a radiation element provided on a first surface side of the first substrate;
a first ground electrode provided in the first substrate and facing the radiation element in a normal direction of the first substrate;
a power inductor provided closer to the second substrate than the first ground electrode; and
an electronic component provided on a fourth surface side of the second substrate and connected to the power inductor,
wherein
the power inductor has
a magnetic core, and
a winding that straddles the first substrate and the second substrate and is wound around the magnetic core, and
a recess in which the magnetic core is disposed is provided on at least one of a second surface side of the first substrate and a third surface side of the second substrate.

2. The antenna module according to claim 1, wherein the magnetic core is disposed to protrude from the second surface toward the second substrate.

3. The antenna module according to claim 2, wherein
the recess is a first recess provided on the second surface side of the first substrate,
a second recess facing the first recess is provided on the third surface side of the second substrate, and
the magnetic core is disposed in the first recess and the second recess.

4. The antenna module according to claim 2, wherein
the recess is a first recess provided on the second surface side of the first substrate,
a second recess facing the first recess is provided on the third surface side of the second substrate,
the magnetic core is split into a first core and a second core,
the first core is disposed in the first recess, and
the second core is disposed in the second recess.

5. The antenna module according to claim 4, further comprising:
a feed line disposed in the first substrate and supplying a signal outputted from the electronic component to the radiation element,
wherein in plan view in the normal direction of the first substrate, the feed line is disposed at a position that does not overlap the power inductor.

6. The antenna module according to claim 4, further comprising:
a feed line disposed in the first substrate and supplying a signal outputted from the electronic component to the radiation element,
wherein assuming the first substrate is viewed in plan view in a direction orthogonal to the normal direction, the feed line is wired at a position that overlaps the power inductor.

7. The antenna module according to claim 4, further comprising:
a feed line disposed in the first substrate and supplying a signal outputted from the electronic component to the radiation element,
wherein
the first substrate is a rectangular substrate with a long side and a short side, and
in plan view in a direction orthogonal to the normal direction of the first substrate and orthogonal to the long side, the feed line is wired at a position that does not overlap the power inductor.

8. The antenna module according to claim 7, further comprising:
a second ground electrode disposed in the second substrate,
wherein, in a normal direction of the second substrate, the power inductor is disposed between the first ground electrode and the second ground electrode.

9. The antenna module according to claim 8, wherein
the electronic component includes
an RFIC (radio frequency integrated circuit), and
a PMIC (power management integrated circuit), and
assuming the second substrate is viewed in plan view in the normal direction, the power inductor overlaps at least one of the RFIC and the PMIC.

10. The antenna module according to claim 9, wherein the power inductor is composed of a toroidal coil.

11. A communication device comprising the antenna module according to claim 10 mounted thereon.

12. A communication device comprising the antenna module according to claim 1 mounted thereon.

13. The antenna module according to claim 1, wherein
the recess is a first recess provided on the second surface side of the first substrate,
a second recess facing the first recess is provided on the third surface side of the second substrate, and
the magnetic core is disposed in the first recess and the second recess.

14. The antenna module according to claim 1, wherein
the recess is a first recess provided on the second surface side of the first substrate,
a second recess facing the first recess is provided on the third surface side of the second substrate,
the magnetic core is split into a first core and a second core,
the first core is disposed in the first recess, and
the second core is disposed in the second recess.

15. The antenna module according to claim 1, further comprising:
a feed line disposed in the first substrate and supplying a signal outputted from the electronic component to the radiation element,
wherein in plan view in the normal direction of the first substrate, the feed line is disposed at a position that does not overlap the power inductor.

16. The antenna module according to claim 1, further comprising:
a feed line disposed in the first substrate and supplying a signal outputted from the electronic component to the radiation element,
wherein assuming the first substrate is viewed in plan view in a direction orthogonal to the normal direction, the feed line is wired at a position that overlaps the power inductor.

17. The antenna module according to claim 1, further comprising:
a feed line disposed in the first substrate and supplying a signal outputted from the electronic component to the radiation element,
wherein
the first substrate is a rectangular substrate with a long side and a short side, and
in plan view in a direction orthogonal to the normal direction of the first substrate and orthogonal to the long side, the feed line is wired at a position that does not overlap the power inductor.

18. The antenna module according to claim 1, further comprising:
a second ground electrode disposed in the second substrate,
wherein, in a normal direction of the second substrate, the power inductor is disposed between the first ground electrode and the second ground electrode.

19. The antenna module according to claim 1, wherein
the electronic component includes
an RFIC (radio frequency integrated circuit), and
a PMIC (power management integrated circuit), and
assuming the second substrate is viewed in plan view in the normal direction, the power inductor overlaps at least one of the RFIC and the PMIC.

20. The antenna module according to claim 1, wherein the power inductor is composed of a toroidal coil.
